(19) United States
(12) Patent Application Publication
(10) Pub. No.: US 2009/0234599 A1
(43) Pub. Date: Sep. 17, 2009

(54) SYSTEM FOR RECORDING CHARGING-HISTORY OF BATTERY MOUNTED ON AUTOMOTIVE VEHICLE

(75) Inventor: Kentarou Watanabe, Yamato-city (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/401,012

(22) Filed: Mar. 10, 2009

(30) Foreign Application Priority Data
Mar. 11, 2008 (JP) 2008-61225

(51) Int. Cl. G01R 31/36

(52) U.S. Cl. 702/63

(57) ABSTRACT

A system for recording a charging history of a battery is mounted on a hybrid vehicle or an electric vehicle. The battery is charged from an outside power source through a plug. The recording system includes a receiver for receiving signals from satellites of a global positioning system, a memory medium and a display device. Every time the battery is charged, a position where the battery is charged is recorded in the memory medium. The position is detected based on the signals from the satellites. A date and time when the battery is charged may be included in the charging-history. The recorded charging history is read-out from the memory medium upon request and displayed on the display device. Thus, the past charging-history is traced. The charging-history may be transmitted to an outside server located at a police station or a charging-service provider to prevent power stealing or to improve services.

### CROSS-REFERENCE TO RELATED APPLICATION

This application is based upon and claims benefit of priority of Japanese Patent Application No. 2008-61225 filed on Mar. 11, 2008, the content of which is incorporated herein by reference.

### BACKGROUND OF THE INVENTION

1. Field of the Invention

The present invention relates to a system for recording charging-history of a rechargeable battery mounted on an automotive vehicle.

2. Description of Related Art

In recent years, a hybrid vehicle that is powered by an electric motor and an engine and an electric vehicle that is solely powered by an electric motor (these vehicle are referred to as an electric-powered vehicles) have been put into actual use. Less carbon dioxide is exhausted from the hybrid vehicle, and no carbon dioxide from the electric vehicle. Therefore, these vehicles are often referred to as environment-friendly vehicles, and it has been desired to make these vehicles more popular.

The electric-powered vehicle has to have a rechargeable battery that is easily charged from an outside power source. An example of the electric-powered vehicle having a battery rechargeable from a home electric plug (so-called plug-in type vehicle) is described in JP-A-2000-203288. Many efforts for putting the plug-in type vehicle into the market is being made these days. Though the plug-in type vehicle is very convenient in charging the on-board battery, a problem such as unauthorized usage of electric power (electric cower stealing) is involved. The electric power stealing from a plug such as a home plug is difficult to trace because it is hard to obtain evidence.

### SUMMARY OF THE INVENTION

The present invention has been made in view of the above-mentioned problem, and an object of the present invention is to provide a system for recording charging-history of an on-board battery that is rechargeable from an outside power source, in which charging-history is recorded to thereby prevent electric power stealing.

The system for recording charging-history of a battery according to the present invention is mounted on a hybrid vehicle that is driven by both an electric motor and an engine or on an electric vehicle that is driven solely by an electric motor. These vehicles (so-called plug-in type vehicles) include a battery which is rechargeable from an outside power source through an electric plug such as a home plug. The recording system includes a position detector having a receiver for receiving signals from satellites of a global positioning system, a display device for displaying information thereon, and a memory medium for recording the charging-history.

When the battery has been charged via an electric plug such as a plug provided in a charging-service facility or a home plug, a position where the battery is charged is recorded in the memory medium as a charging-history. The position is detected based on the signals received from the OPS satellites. The recorded charging-history is read-out from the memory medium and displayed on the display device upon request of a user. In this manner, a position where the battery is charged is traced to thereby find whether the battery is charged at a place where the charging is not allowed. Thus, electric power stealing is watched and prevented.

A date and time may be additionally included in the charging-history to trace past charging more accurately. A wireless transmitter/receiver communicating with outside devices such as a server maybe included in the recording system. The charging-history may be transmitted upon request to the outside server which is located at a police station or a charging-service provider. It is possible for the police to watch and prevent the electric power stealing and for the charging-service provider to improve facilities and services according to information in the charging-history. It is also possible to automatically transmit newly added charging-history to the outside server. Old records of the charging-history may be automatically deleted from the memory medium to effectively use its capacity.

According to the present invention, the charging history of the battery is recorded, and the recorded history is retrieved at any time to thereby watch and prevent unauthorized charging such as power stealing. In addition, a charging-service provider is able to improve its facilities and services according to the information in the charging history. Other objects and features of the present invention will become more readily apparent from a better understanding of the preferred embodiments described below with reference to the following drawings.

### BRIEF DESCRIPTION OF THE DRAWINGS

FIG. 1 is a block diagram showing an entire structure of a hybrid vehicle that is driven by both an electric motor and an engine;

FIG. 2 is a block diagram showing a system for recording charging history of a battery mounted on an electric-powered vehicle;

FIG. 3 is a flowchart showing a process of recording the charging-history of an on-board battery;

FIG. 4 is a flowchart showing a process of reading-out charging-history recorded in the system;

FIG. 5 is a flowchart showing a process of transmitting the charging history to outside devices; and

FIG. 6 is a flowchart showing a process of deleting records of the charging-history recorded in the system.

### DETAILED DESCRIPTION OF THE PREFERRED EMBODIMENTS

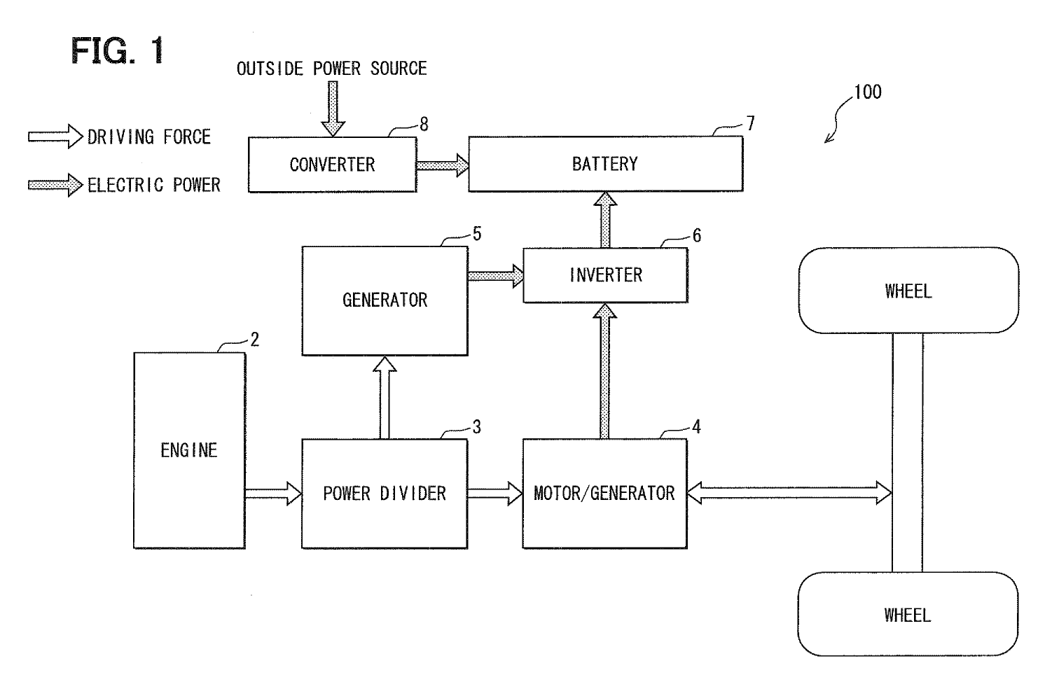

A first embodiment of the present invention will be described with reference to FIGS. 1-4. The system for recording charging-history of a battery according to the present invention is mounted on a vehicle such as a hybrid vehicle 100 shown in FIG. 1. The hybrid vehicle 100 is driven by an electric motor/generator 4 and an Internal combustion engine 2. The motor/generator 4 also functions as a generator. Power of an engine 2 is divided into power to drive wheels of the vehicle and a power to drive a generator 5 by a power divider 3. The power to drive the wheels is also used to drive the motor/generator 4.

Electric power generated by the generator 5 and the motor/generator 4 is supplied to the battery 7 through an inverter 6 to charge the battery 7. The inverter 6 changes alternating current generated by the generator 5 and the motor/generator 4 to direct current and supplies the direct current to the battery 7 to charge it. The inverter 6 also changes the direct current of the battery 7 to alternating current and supplies the alternating current to the motor/generator 4 to operate it as a motor to drive the wheels. A converter 8 for converting alternating current supplied from an outside power source to direct current for charging the battery 7 is also included in the hybrid vehicle 100. The outside power source is connected to the converter 8 through a plug, for example.

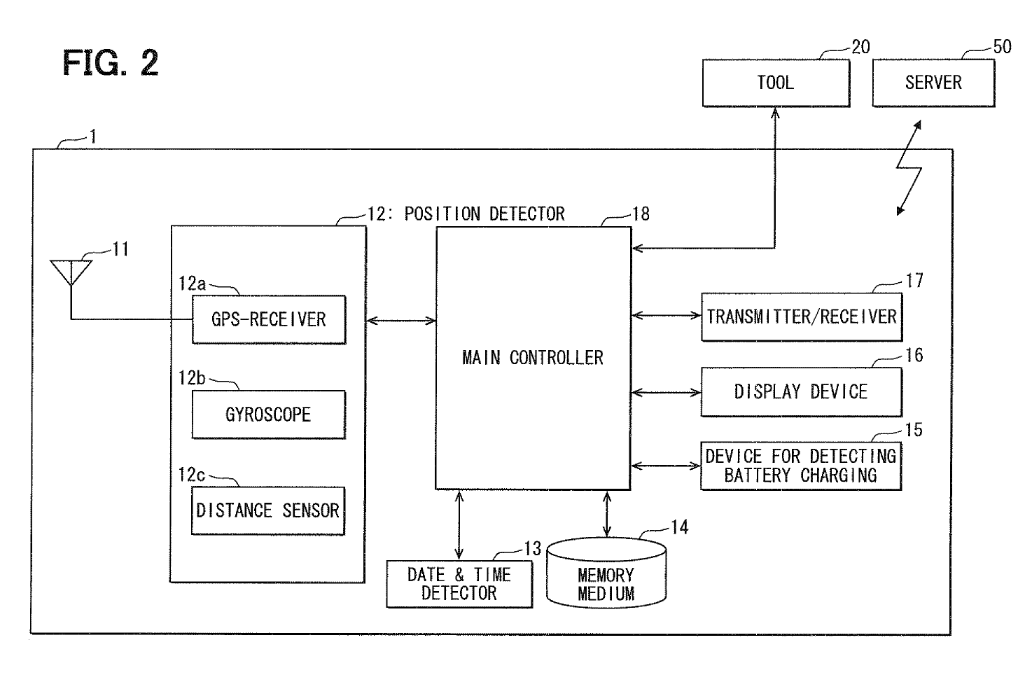

With reference to FIG. 2, a system 1 for recording charging-history of the battery 7 will be described. The recording system 1 is mounted on the vehicle. The recording system 1 includes a GPS-antenna 11 (an antenna for receiving signals from a global positioning system), a position detector 12, a date and time detector 13, a memory medium 14, a device 15 for detecting battery charging, a display device 16, a transmitter/receiver 17, and a main controller 18.

The GPS antenna 11 receives signals from satellites of the global positioning system. The position detector 12 is composed of a GPS-receiver 12a, a gyroscope 12b and a distance sensor 12c. The GPS-receiver 12a detects a position, a driving direction and a driving speed of the vehicle based on the signals received via the CPS antenna 11. The gyroscope 12b detects an amount of rotational force imposed on the vehicle. The distance sensor 12c detects a driven distance of the vehicle based on acceleration imposed on the vehicle in a front-to-rear direction. Since the GPS-receiver 12a, the gyroscope 12b and the distance sensor 12c include respective detection errors, these devices are used to compensate respective detection errors one another.

The date and time detector 13 calculates the date and time based on time data included in the signals sent from the GPS-satellites. The time data included in the signals are very accurate because an atomic clock is mounted on the satellite. The memory medium 14 memorizes the charging-history of the battery including a position where the battery is charged and date and time when the battery is charged. The determining device 15 determines a charging condition of the battery 7 based on an amount of current supplied from an outside power source to the battery. The display device 16 composed of a device such as a liquid crystal display panel displays information based on commands from the main controller 18.

The transmitter/receiver 17 wirelessly receives information sent from an outside server 50 and inputs the received information to the main controller 18. The transmitter/receiver 17 also wirelessly transmits information such as the charging-history to the outside server 50 based on commands from the main controller 18. The main controller 18 is a known microcomputer including CPU, ROM, RAM and connecting buses.

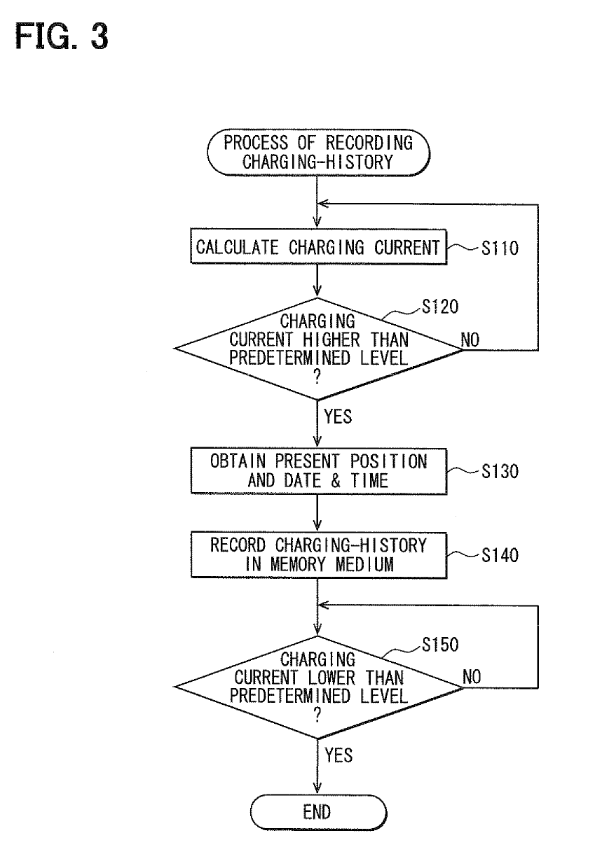

With reference to FIG. 3, a process of recording the charging history of the battery 7 will be described. At step S110, charging current supplied from the outside power source to the battery 7 is calculated based on outputs of the determining device 15. At step S120, whether the charging current is higher than a predetermined level is checked (i.e., whether the battery is being charged or not is determined) If the charging current is not higher than the predetermined level (the battery is not being charged), the process returns to step S110. If the charging current is higher than the predetermined level (the battery is being charged), the process proceeds to step S130.

At step S130, the present position of the vehicle is obtained from the position detector 11, and the present date and time are obtained from the date and time detector 13. Then, at step S140, the charging-history, i.e., the position where the battery is charged and the date and time when the battery is charged, is recorded in the memory medium 14. The charging-history is accumulated as long as a capacity of the memory medium 14 permits, and the records are deleted from the oldest one to allow recording of new data. Then, at step S150, whether the charging current is lower than a predetermined level is checked. If it is determined that the charging current is not lower than the predetermined level, the process stays at step S150 until the charging current becomes lower than the predetermined level. If the charging current becomes lower than the predetermined level, it is determined that the charging of the battery is terminated, and the process comes to the end. In this manner, the position where the battery is charged and the date and time when the battery is charged are recorded in the memory medium 14. The charging history is once recorded every time when the battery is charged.

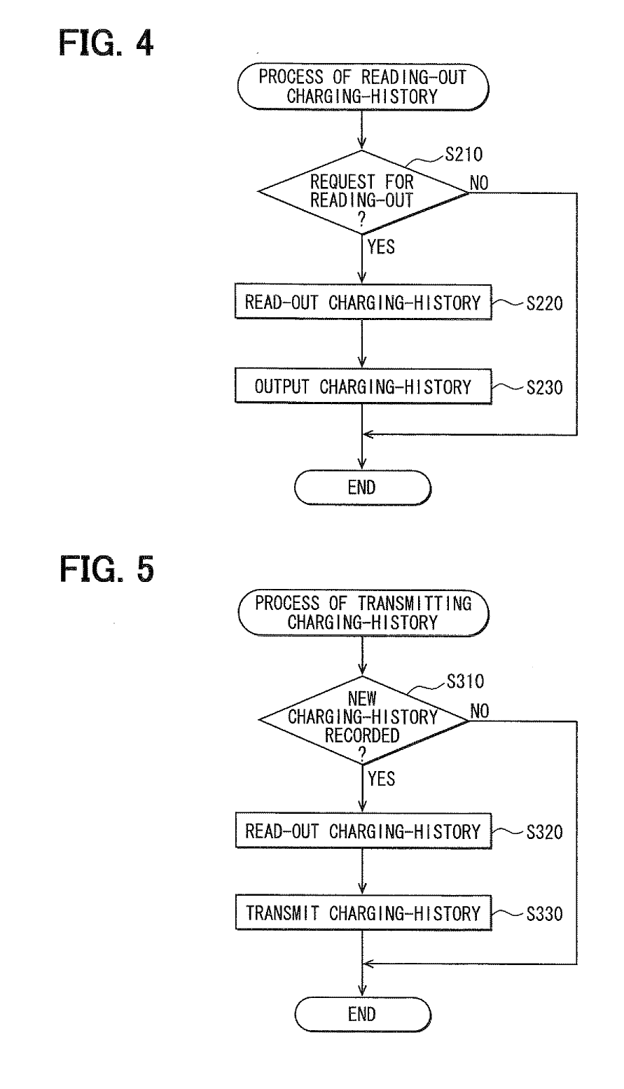

With reference to FIG. 4, a process of reading-out the charging-history from the memory medium 14 will be described. At step S210, whether a request for reading-out the charging-history is made or not is determined. The request for reading-out is made in the following manner: (1) the request is inputted by a user to an inputting device (not shown) in the system 1; (2) the request is inputted from an outside tool 20 (refer to FIG. 2); or (3) the request is wirelessly sent from the server 50 to the transmitter/receiver 17. If it is determined that the request for reading-out is not inputted at step S210, the process directly comes to the end. If the request is made, the process proceeds to step S220, where the charging-history is read-out from the memory medium 14. At step S230, the read-out charging-history is outputted according to commands of the user. It may be displayed on the display device 16, may be sent to the tool 20, or may be wirelessly transmitted to the server 50 through the transmitter/receiver 17. Then, the process comes to the end.

By reading-out the charging-history, the position (place) where the battery is charged and the date and time when the battery is charged are easily checked at any time. In this manner, whether the battery is charged at a position where the battery charging is not permitted and whether the battery is charged at the date and time when the battery charging is not permitted can be easily determined. If the battery charging is done in an impermissible manner (position and time), there is a possibility of electric power stealing. Thus, the electric power stealing can be watched and prevented by using the recording system 1 of the present invention.

The server 50 (FIG. 2) may be positioned at a police station or at a charging-service provider. IL the server 50 is positioned at a police station, unlawful or unauthorized battery charging can be watched by police, preventing the power stealing. If the server 50 is positioned at a charging-service provider, the provider is able to easily obtain information about needs of the charging. For example, the provider is able to know the most frequently used position of charging and the date and time when the charging is most frequently performed. According to the needs of users who use the charging service facilities, the charging-service provider may effectively improve the facilities and services. In addition, information about the charging history obtained from the server 50 positioned at the charging-service provider may be sent to police if such is necessary.

A second embodiment of the present invention will be described with reference to FIG. 5. In the second embodiment, a process of wirelessly transmitting the charging history (shown in FIG. 5) is performed In addition to the processes (shown in FIGS. 3 and 4) performed in the first embodiment described above. Other structures and functions are the same as those in the first embodiment. The transmitting process shown in FIG. 5 is periodically performed by the CPU in the main controller 18.

At step S310, whether anew charging-history is recorded in the memory medium 14 is determined. If it is determined that no new charging-history is recorded, the process directly comes to the end. If it is determined that a new charging-history is recorded, the process proceeds to step S320, where the new charging-history is read-out from the memory medium 14. Then, at step S330, the newly read-out charging-history is wirelessly transmitted to the server 50. In this manner, the information in the server 50 is automatically renewed, and watching of the power stealing and/or improvement of the charging-service is more effectively performed.

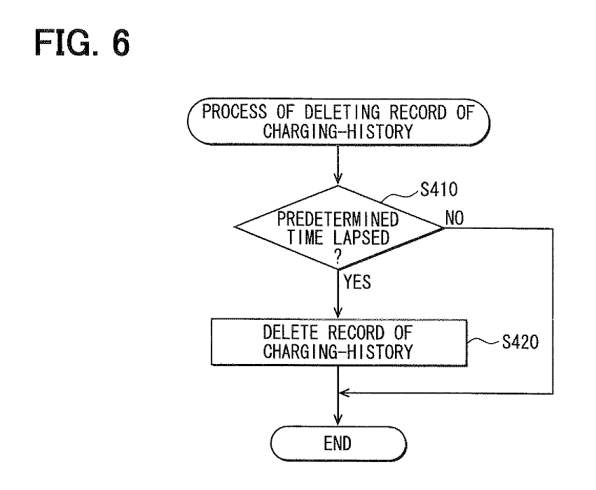

A third embodiment of the present invention will be described with reference to FIG. 6. In this embodiment, a process of deleting old records (shown in FIG. 6) is performed in addition to the processes performed in the first embodiment. Other structures and functions of the third embodiment are the same as those in the first embodiment. The process of deleting is performed for each charging-history recorded in the memory medium 14.

At step S410, whether a predetermined time has lapsed after the charging-history is recorded is determined. If it is determined that the predetermined time has not lapsed, the process directly comes to the end. If it is determined that the predetermined time has lapsed, the process proceeds to step S420, where the charging-history (the old charging history) is deleted from the records. Then, the process comes to the end, in this manner, the memory medium 14 is prevented from being unnecessarily occupied by old records.

The present invention is not limited to the embodiments described above, but it maybe variously modified. For example, the charging-history may include only the position (place) where the battery is charged. If the charging position is traced from the records in the memory medium 14, it can be judged whether or not the charging position is a position where charging of the battery is allowed. Thus, electric power stealing can be traced or prevented. Further, it is possible for the charging service provider to know which facilities are frequently used and to improve the charging service based or such information.

Though the recording system 1 is mounted on the hybrid vehicle 100 in the foregoing embodiment, it is, of course, possible to mount it on an electric vehicle that is driven solely by an electric motor. Instead of using the date and time sent form the GPS satellites, it is possible to include a clock inside the recording system 1. Further, an amount of electric power and a period of time used for charging the battery may be recorded in the memory medium 14 as the charging-history in addition to the position where the battery is charged and the date and time when the battery is charged. The charging-history including the electric power used for charging may be transmitted to the server 50, and the fee for the charging may be processed based on the charging-history. In this case, an invoice for the charging fee may be sent to the user. Alternatively, the charging fee may be automatically paid from a bank account of the user, or paid by a credit card. The charging-history may be wirelessly Transmitted to other vehicles or to police vehicles. The police may watch and prevent the electric power stealing.

While the present invention has been shown and described with reference to the foregoing preferred embodiments, it will be apparent to those skilled in the art that changes in form and detail may be made therein without departing from the scope of the invention as defined in the appended claims.

What is claimed is:

1. A system for recording charging-history of a battery that is rechargeable from an outside power source and supplies electric power to an electric motor for driving an automotive vehicle, the system comprising:
a position detector for detecting a present position of the vehicle;
means for determining whether the battery has been charged; and
means for recording the charging history of the battery, wherein the recording means records the present position of the vehicle where the battery is charged when the determining means determines that the battery has been charged.

2. The recording system as in claim 1, further including means for detecting a date and time, wherein the recording means further records the date and time when the battery is charged when the determining means determines that the battery has been charged.

3. The recording system as in claim 1, wherein: the position detector includes a receiver for receiving signals from satellites of a global positioning system; and the present position of the vehicle is detected based on the signals.

4. The recording system as in claim 2, wherein: the position detector includes a receiver for receiving signals from satellites of a global positioning system; and the date and time when the battery is charged is detected from the signals.

5. The recording system as in claim 1, further including a display device for displaying information and means for finding whether a request for reading-out the charging history recorded in the recording means is inputted, wherein the charging history is read-out and displayed on the display device when the request for reading-out is inputted.

6. The recording system as in claim 1, further including means for communicating with outside devices, wherein the charging-history recorded in the recording means is read-out and transmitted to the outside devices through the communicating means when a request for transmitting the charging-history is inputted.

7. The recording system as in claim 1, further including means for communicating with outside devices, wherein, when a new record of the charging-history is added to the recording means, the new record is automatically transmitted to the outside devices through the communicating means.
